(19) United States
(12) Patent Application Publication
(10) Pub. No.: US 2026/0344513 A1
(43) Pub. Date: Oct. 29, 2026

(54) PACKAGE STRUCTURE

(71) Applicant: Advanced Semiconductor Engineering, Inc., Kaohsiung (TW)

(72) Inventors: Yenchih LIU, Kaohsiung (TW); Yichung LIN, Kaohsiung (TW); Sheng-Hong CHEN, Kaohsiung (TW); Yueh-Ju LIN, Kaohsiung (TW); Chih-Cheng HUNG, Kaohsiung (TW)

(73) Assignee: Advanced Semiconductor Engineering, Inc., Kaohsiung (TW)

(21) Appl. No.: 19/190,484

(22) Filed: Apr. 25, 2025

(51) Int. Cl. H10W 90/00; H10W 46/00; H10W 70/09; H10W 70/60; H10W 70/652; H10W 74/10; H10W 90/22; H10W 90/28

(52) U.S. Cl. CPC H10W 90/00; H10W 46/00; H10W 46/301; H10W 70/09; H10W 70/60; H10W 70/6528; H10W 74/111; H10W 90/22; H10W 90/28; H10W 90/754

(57) ABSTRACT

The present disclosure relates to a package structure. The package structure includes a first semiconductor component, a second semiconductor component disposed over the first semiconductor component, a plurality of alignment wires disposed on the second semiconductor component, and an encapsulant encapsulating the first semiconductor component, the second semiconductor component, and the plurality of alignment wires. The encapsulant has a top surface exposing top surfaces of the plurality of alignment wires. The top surfaces of the plurality of alignment wires constitute an alignment pattern in a top view.

### BACKGROUND

### 1. Technical Field

The present disclosure relates generally to a package structure, and more particularly to a semiconductor package structure utilizing vertical wires as alignment marks.

### 2. Description of the Related Art

Vertical fan-out (VFO) configuration of package structures uses wire bonding for vertical electrical connections. The structure enables vertical connections for transmitting electrical signals between a die or IC and a redistribution layer (RDL) disposed thereon. However, after grinding preparatory to formation of the RDL, only the endpoints of the wires remain, and since the wires are identical in size and shape, it can be difficult to accurately capture the correction position during subsequent alignment, leading to possible misalignment. Therefore, an improved package structure is called for.

### SUMMARY

In some embodiments, a package structure includes a first semiconductor component, a second semiconductor component disposed over the first semiconductor component, a plurality of alignment wires disposed on the second semiconductor component, and an encapsulant encapsulating the first semiconductor component, the second semiconductor component, and the plurality of alignment wires. The encapsulant has a top surface exposing top surfaces of the plurality of alignment wires. The top surfaces of the plurality of alignment wires constitute an alignment pattern in a top view.

In some embodiments, a package structure includes a first die, a second die, an encapsulant, a plurality of first conductive wires, a plurality of second conductive wires, and a plurality of first alignment wires. The first die has a first active surface, and the second die is disposed below the first die and has a second active surface. The encapsulant encapsulates the first die and the second die and has a first surface, which includes a first region, a second region, and an alignment region between the first region and the second region. The plurality of first conductive wires are disposed on the second active surface of the second die and encapsulated by the encapsulant, and top surfaces of the plurality of first conductive wires are exposed in the first region of the encapsulant. The plurality of second conductive wires are disposed on the second active surface of the second die and encapsulated by the encapsulant, and top surfaces of the plurality of second conductive wires are exposed in the second region of the encapsulant. The plurality of first alignment wires extend between the first active surface of the first die and the first surface of the encapsulant, and top surfaces of the plurality of first alignment wires are exposed in the alignment region and constitute a first alignment mark.

In some embodiments, a package structure includes an electronic component having an active surface, an alignment wire disposed on the active surface, a conductive wire disposed on the active surface, and an encapsulant encapsulating the electronic component, the alignment wire, and the conductive wire. Top surfaces of the alignment wire and the conductive wire are exposed by the encapsulant. The conductive wire is closer to an edge of the electronic component than the alignment wire is.

### BRIEF DESCRIPTION OF THE DRAWINGS

Aspects of the present disclosure are better understood from the following detailed description when read with the accompanying drawings. It is noted that various features may not be drawn to scale, and the dimensions of the various features may be arbitrarily increased or reduced for clarity of discussion.

FIG. 1 is a cross-section of a package structure, in accordance with some embodiments of the present disclosure.

FIG. 2A is an enlarged view of region “2A” in FIG. 1, in accordance with some embodiments of the present disclosure.

FIG. 2B is an enlarged view of region “2B” in FIG. 1, in accordance with some embodiments of the present disclosure.

FIG. 2C is an enlarged view of region “2C” in FIG. 1, in accordance with some embodiments of the present disclosure.

FIG. 3 is a top view of a package structure, in accordance with some embodiments of the present disclosure.

FIG. 4A is an enlarged view of region “4” in FIG. 3, in accordance with some embodiments of the present disclosure.

FIG. 4B is an enlarged view of region “4” in FIG. 3, in accordance with some embodiments of the present disclosure.

FIG. 4C is an enlarged view of region “4” in FIG. 3, in accordance with some embodiments of the present disclosure.

FIG. 4D is an enlarged view of region “4” in FIG. 3, in accordance with some embodiments of the present disclosure.

FIG. 5 is a cross-section of a package structure, in accordance with some embodiments of the present disclosure.

FIG. 6 is a top view of a package structure, in accordance with some embodiments of the present disclosure.

FIG. 7A, FIG. 7B, FIG. 7C, FIG. 7D, FIG. 7E, FIG. 7F, and FIG. 7G illustrate one or more operations of a method for manufacturing a package structure, in accordance with some embodiments of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

The following disclosure provides different embodiments, or examples, for implementing different features of the provided subject matter. Specific examples of components and embodiments are recited herein. These are, of course, merely examples and are not intended to be limiting. In the present disclosure, reference to the formation of a first feature over or on a second feature in the description that follows may include embodiments in which the first and second features are formed in direct contact, and may also include embodiments in which additional features may be formed between the first and second features, such that the first and second features may not be in direct contact. The present disclosure may repeat reference numerals and/or letters in the various examples. This repetition is for simplicity and clarity and does not in itself dictate a relationship between the various embodiments and/or configurations discussed.

Embodiments of the present disclosure are discussed in detail as follows. It should be appreciated, however, that the present disclosure provides many applicable concepts that can be embodied in a wide variety of specific contexts. The specific embodiments discussed are merely illustrative and do not limit the scope of the disclosure.

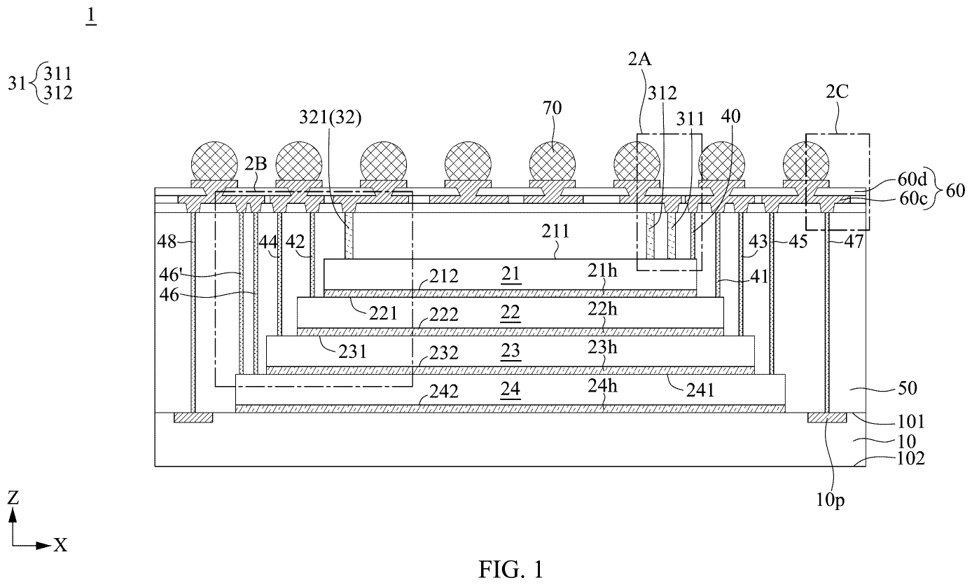

FIG. 1 is a cross-section of a package structure 1, in accordance with some embodiments of the present disclosure. The package structure 1 may include a substrate 10, one or more electronic components (or semiconductor components) 21, 22, 23, and 24, alignment marks 31 and 32, conductive wires 40, 41, 42, 43, 44, 45, 46, 46′, 47, and 48, an encapsulant 50, a redistribution layer (RDL) 60, and one or more electrical contacts 70.

The package structure 1 may be or include a memory stack, interposer, package-on-package (PoP), fan-out package, fan-out wafer-level packaging (FOWLP), or the like.

Embodiments of the present disclosure constitute a package structure including one or more wire bondings (such as alignment wires 311 and 312) as alignment marks on the die to be molded. After grinding, the alignment marks arranged in a specific pattern can be easily identified, thereby enhancing the alignment to form a redistribution layer thereon. In addition, the pitch and size of the wire bonding as the alignment marks can differ from that of other wire bondings for better identification. The differences enhance identification and recognition during alignment, improving yield. Furthermore, the wire bonding can have a low aspect ratio, for instance, of 1:20. This characteristic is advantageous as it allows integration of these wires into thicker structures, thereby expanding the potential applications and versatility of the package structure. The incorporation of vertical wire bonding as alignment marks not only enhances the accuracy of the alignment process but also contributes to the vertical electrical connection. This proposed approach improves manufacturing efficiency and performance for electronic devices.

The substrate 10 may include, for example, a printed circuit board, such as a paper-based copper foil laminate, a composite copper foil laminate, or a polymer-impregnated glass-fiber-based copper foil laminate. The substrate 10 may include an interconnection structure, such as a plurality of conductive traces and/or a plurality of conductive vias. In some embodiments, the substrate 10 includes a ceramic material, a metal plate, an organic substrate, or a leadframe. In some embodiments, the substrate 10 may include a two-layer substrate which includes a core layer and a conductive material and/or structure disposed on an upper surface and a bottom surface of the substrate 10. The conductive material and/or structure may include a plurality of conductive traces. The substrate 10 may include a top surface 101 and a bottom surface 102 opposite to the top surface 101. In some embodiments, the substrate 10 includes one or more pads 10p exposed by the top surface 101 or the bottom surface 102.

The electronic components 21, 22, 23, and 24 may be disposed on the top surface 101 of the substrate 10. The electronic components 21, 22, 23, and 24 may be stacked. In some embodiments, the electronic component 24 may be disposed between the electronic component 23 and the substrate 10. The electronic component 24 may be attached to the substrate 10 via an adhesive layer 24h. In some embodiments, the electronic component 23 may be disposed between the electronic components 22 and 24. The electronic component 23 may be attached to electronic component 24 via an adhesive layer 23h. In some embodiments, the electronic component 22 may be disposed between the electronic components 21 and 23. The electronic component 22 may be disposed between the electronic component 21 and the substrate 10. The electronic component 22 may be attached to the electronic component 23 via an adhesive layer 22h. In some embodiments, the electronic component 21 may be disposed on the electronic component 22. The electronic component 21 may be attached to the electronic component 22 via an adhesive layer 21h.

Each of the electronic components 21, 22, 23, and 24 may be a chip or die including a semiconductor substrate, one or more integrated circuit devices, and one or more overlying interconnection structures therein. The integrated circuit devices may include active devices such as transistors and/or passive devices such resistors, capacitors, inductors, or a combination thereof. In some arrangements, the electronic components 21, 22, 23, and 24 include an active device, e.g., an ASIC, a PMIC, or the like. For example, the electronic components 21, 22, 23, and 24 may be or include a storage component or memory, e.g., a dynamic random access memory (DRAM).

In some embodiments, the electronic component 21 may have an active surface 211 and a backside surface 212 opposite to the active surface 211. The active surface 211 may face away from the substrate 10. The backside surface 212 may be attached to an active surface 221 of the electronic component 22 through the adhesive layer 21h.

In some embodiments, each of the electronic components 22, 23, and 24 may have an active surface 221, 231, and 241 facing the electronic component 21. The electronic components 21, 22, 23, and 24 may have different sizes (such as thickness and/or width). For example, thicknesses of the electronic components 21, 22, 23, and 24 may vary. In some embodiments, the lower electronic component that is closer to the substrate 10 may be larger. In some embodiments, the electronic component 22 can be larger than electronic component 21. The electronic component 23 can be larger than electronic component 22. The electronic component 24 can be larger than electronic component 23.

Referring to FIG. 1, both sides of the active surface 221 of the electronic component 22 may be exposed by the electronic component 21. Both sides of the active surface 231 of the electronic component 23 may be exposed by the electronic component 22. Both sides of the active surface 241 of the electronic component 24a may be exposed by the electronic component 23. Accordingly, one or more conductive wires 41, 42, 43, 44, 45, 46, and 46′ may be disposed in the exposed portion of the active surfaces 221, 231, and 241.

In another embodiment, the size of the electronic components 21, 22, 23, and 24 may be substantially identical. For example, the width and/or the thickness of the electronic components 21, 22, 23, and 24 may be the same. In such a case, the electronic components 21, 22, 23, and 24 may be staggered (not shown) so that a part of the active surfaces of the electronic components 22, 23, 24 can be exposed to facilitate the vertical electrical connection. For example, the electronic components 21 and 22 can be staggered such that an exposed portion of the electronic component 22 is exposed by the electronic component 21. Accordingly, the conductive wires may be located at the exposed portion.

The RDL 60 may be disposed on the substrate 10 and the electronic components 21, 22, 23, and 24. In some embodiments, the RDL 60 includes dielectric layers 60d and conductive layers 60c at least partially covered by the dielectric layers 60d. The conductive layers 60c may include conductive traces, pads, and conductive vias. The conductive layers 60c may be or include a conductive material, e.g., for example, aluminum (Al), copper (Cu), chromium (Cr), tin (Sn), gold (Au), silver (Ag), nickel (Ni), stainless steel, a mixture, an alloy, or other combination thereof. In some embodiments, the width of the RDL 60 may be substantially identical to the width of the substrate 10.

The alignment mark 31 may be disposed on and connected to the active surface 211 of the electronic component 21. In some embodiments, the alignment mark 31 may include alignment wires 311 and 312 extending between the RDL 60 and the active surface 211 of the electronic component 21. The alignment wires 311 and 312 may be disposed on and connected to a pad of the electronic component 21, respectively. In some embodiments, the alignment wires 311 and 312 are connected to the same pad of the electronic component 21. The dielectric layer 60d may cover top surfaces of the alignment wires 311 and 312. The alignment wire 311 may be connected to the conductive layer 60c of the RDL 60 to provide a vertical electrical connection between the RDL 60 and the electronic component 21. The alignment wire 312 may be adjacent to the alignment wire 311 and connected to the dielectric layer 60d of the RDL 60. In some embodiments, the alignment wire 311 may be substantially parallel to the alignment wire 312. In some embodiments, the alignment wire 311 may be substantially identical to that of the alignment wire 312. In some embodiments, a diameter of the alignment wire 311 may be substantially identical to that of the alignment wire 312.

Similarly, the alignment mark 32 may be disposed on and connected to the active surface 211 of the electronic component 21. The alignment mark 32 may be spaced apart from the alignment mark 31. In some embodiments, the alignment marks 31 and 32 may be arranged at opposite sides of the electronic component 21. For example, the alignment marks 31 and 32 may be arranged adjacent to opposite edges of the electronic component 21, such that the boundary of the electronic component 21 can be identified when forming the RDL 60. In some embodiments, the alignment marks 31 and 32 may be disposed at corners of the electronic component 21.

In some embodiments, the alignment mark 32 may include one or more alignment wires 321 extending between the RDL 60 and the active surface 211 of the electronic component 21. The alignment wires 321 may be disposed on and connected to a pad of the electronic component 21. The dielectric layer 60d may cover the top surface of the alignment wire 321. The alignment wire 321 may electrically connect to one of the conductive layers 60c of the RDL 60. In other embodiments, the alignment wire 321 may be connected to the dielectric layer 60d of the RDL 60. In some embodiments, the alignment wire 321 may be substantially parallel to the alignment wire 311 and/or 312. In some embodiments, the alignment wire 321 may be substantially identical to that of the alignment wire 311. In some embodiments, a diameter of the alignment wire 321 may be substantially identical to that of the alignment wire 311. In other embodiments, the diameter of the alignment wire 321 may be different from that of the alignment wire 311.

In some embodiments, the alignment wires 311, 312, and 321 may be formed by vertical wire bonding. The alignment wires 311, 312, and 321 may be or include a conductive pillar, or other suitable conductive interconnectors. The alignment wires 311, 312, and 321 may be or include a conductive material, e.g., for example, copper (Cu), aluminum (Al), chromium (Cr), tin (Sn), gold (Au), silver (Ag), nickel (Ni), platinum (Pt), a mixture, an alloy, or other combination thereof.

The conductive wire 40 may be connected to the active surface 211 of the electronic component 21. The conductive wire 40 may be connected to a pad (not shown) of the electronic component 21. In some embodiments, the conductive wire 40 may extend between the RDL 60 and the active surface 211 of the electronic component 21. The conductive wire 40 may electrically connect to one of the conductive layer 60c of the RDL 60. The conductive wire 40 may be spaced apart from the alignment wire 311 by a distance. The alignment mark 31 may be disposed between the alignment mark 32 and the conductive wire 40. The conductive wire 40 is closer to an edge of the electronic component 21 than the alignment wire 311 is. In some embodiments, the conductive wire 40 is electrically connected to the active surface 211 of the electronic component 21. In some embodiments, the conductive wire 40 may be substantially identical to that of the alignment wires 311, 312, and 321. The diameter of the conductive wire 40 may be different from that of the alignment wires 311, 312, and 321. For example, the diameter of the conductive wire 40 may be less than that of the alignment wire 311. In some embodiments, the diameter of the conductive wire 40 may be about 18 to 25 μm. The diameter of the alignment wire 311 may be about 18 to 60 μm, preferably 40 to 60 μm.

The conductive wires 41 and 42 may be disposed on opposite sides of the active surface 221 of the electronic component 22 exposed by the electronic component 21. The conductive wires 41 and 42 may extend between the RDL 60 and the active surface 221. The conductive wires 41 and 42 may be connected to a pad (not shown) of the electronic component 22. The conductive wires 41 and 42 may electrically connect to one of the conductive layer 60c of the RDL 60.

The conductive wires 41 may be spaced apart from the alignment wire 311 by a distance. The conductive wire 41 may be spaced apart from the conductive wire 40. The conductive wire 40 may be disposed between the alignment mark 31 and the conductive wire 41.

The conductive wire 42 may be spaced apart from the alignment wire 321 by a distance. The alignment mark 31 may be disposed between the conductive wires 41 and 42. That is, the alignment wires 311 and 312 may be disposed between the conductive wires 41 and 42. The conductive wire 42 may be close to an edge of the electronic component 22.

In some embodiments, the length of the conductive wires 41 and 42 may be different from that of the alignment wires 311, 312, and 321 and the conductive wire 40. For example, the length of the conductive wires 41 and 42 may be greater than that of the alignment wires 311, 312, and 321 and the conductive wire 40. In some embodiments, a bottom end of the alignment wire 311 may be closer to a top surface 501 (i.e., the grinded surface) of the encapsulant 50 than a bottom end of the conductive wires 41 and 42 is. The diameter of the conductive wires 41 and 42 may be substantially identical to that of the conductive wire 40.

The conductive wires 43 and 44 may be disposed on opposite sides of the active surface 231 of the electronic component 23 exposed by the electronic component 22. The conductive wires 43 and 44 may extend between the RDL 60 and the active surface 231. The conductive wires 43 and 44 may be disposed on and connected to a pad (not shown) of the electronic component 23. The conductive wires 43 and 44 may electrically connect to one of the conductive layer 60c of the RDL 60.

The conductive wire 43 may be spaced apart from the conductive wire 41 by a distance. The conductive wire 41 may be disposed between the alignment wire 311 and the conductive wire 43. The conductive wire 43 may be close to an edge of the electronic component 23. The conductive wire 44 may be spaced apart from the conductive wire 42 by a distance. The conductive wire 42 may be disposed between the alignment wire 321 and the conductive wire 44. The conductive wire 44 may be close to an edge of the electronic component 23.

In some embodiments, the length of the conductive wires 43 and 44 may be different from that of the alignment wires 311, 312, and 321 and the conductive wires 40, 41, and 42. For example, the length of the conductive wires 43 and 44 may be greater than that of the alignment wires 311, 312, and 321 and the conductive wires 40, 41, and 42. The conductive wires 43 and 44 may be longer than the conductive wires 41 and 42. The diameter of the conductive wires 43 and 44 may be substantially identical to that of the conductive wire 40.

The conductive wires 45 may be disposed on one side of the active surface 241 of the electronic component 24 exposed by the electronic component 23, and the conductive wires 46 and 46′ may be disposed on the opposite side of the active surface 241 of the electronic component 24 exposed by the electronic component 23. The conductive wires 45, 46, and 46′ may extend between the RDL 60 and the active surface 241. The conductive wires 45, 46, and 46′ may be disposed on and connected to a pad (not shown) of the electronic component 24. The conductive wire 45 may electrically connect to one of the conductive layer 60c of the RDL 60. The conductive wire 46 may electrically connect to one of the conductive layer 60c of the RDL 60. The conductive wire 46′ may electrically connect to one of the conductive layer 60c of the RDL 60.

The conductive wire 45 may be spaced apart from the conductive wire 43 by a distance. The conductive wire 43 may be disposed between the conductive wire 41 and the conductive wire 45. The conductive wire 45 may be close to an edge of the electronic component 24. The conductive wire 46 may be spaced apart from the conductive wire 44 by a distance. The conductive wire 44 may be disposed between the conductive wire 42 and the conductive wire 46. The conductive wire 46 may be close to an edge of the electronic component 24. The conductive wire 46′ may be spaced apart from the conductive wire 46 by a distance. The conductive wire 46 may be disposed between the conductive wire 44 and the conductive wire 46′. The conductive wire 46′ may be close to an edge of the electronic component 24. The conductive wire 46′ is closer to the edge of the electronic component 24 than the conductive wire 46 is.

In some embodiments, the length of the conductive wires 45, 46, and 46′ may be different from that of the alignment wires 311, 312, and 321 and the conductive wires 40 to 44. For example, the length of the conductive wires 45, 46, and 46′ may be greater than that of the alignment wires 311, 312, and 321 and the conductive wires 40 to 44. The conductive wires 45, 46, and 46′ may be longer than the conductive wires 43 and 44. The diameter of the conductive wires 45, 46, and 46′ may be substantially identical to that of the conductive wire 40.

The conductive wires 47 and 48 may be disposed on opposite sides of the top surface 101 of the substrate 10. The conductive wires 47 and 48 may extend between the RDL 60 and the top surface 101 of the substrate 10. The conductive wires 47 and 48 may electrically connect to pads 10p of the substrate 10. The conductive wires 47 and 48 may electrically connect to one of the conductive layer 60c of the RDL 60.

The conductive wire 47 may be spaced apart from the conductive wire 45 by a distance. The conductive wire 45 may be disposed between the conductive wire 43 and the conductive wire 47. The conductive wire 48 may be spaced apart from the conductive wire 46′ by a distance. The conductive wire 46′ may be disposed between the conductive wire 46 and the conductive wire 48.

In some embodiments, the length of the conductive wires 47 and 48 may be different from that of the alignment wires 311, 312, and 321 and the conductive wires 40 to 46′. For example, the length of the conductive wires 47 and 48 may be greater than that of the alignment wires 311, 312, and 321 and the conductive wires 40 to 46′. The conductive wires 47 and 48 may be longer than the conductive wires 45, 46, and 46′. The diameter of the conductive wires 47 and 48 may be substantially identical to that of the conductive wire 40.

The conductive wires 40 to 48 may be disposed over the top surface 101 of the substrate 10 and connected to the RDL 60. The conductive wires 40 to 48 may be formed by vertical wire bonding. In some embodiments, the conductive wires 40 to 48 may have the same diameter. The conductive wires 40 to 48 may be or include a conductive pillar, or other suitable conductive interconnectors. The conductive wires 40 to 48 may be or include a conductive material, e.g., for example, copper (Cu), aluminum (Al), chromium (Cr), tin (Sn), gold (Au), silver (Ag), nickel (Ni), platinum (Pt), a mixture, an alloy, or other combination thereof. As the conductive wires 40 to 48 may be connected to different electronic components, their length may correspondingly vary.

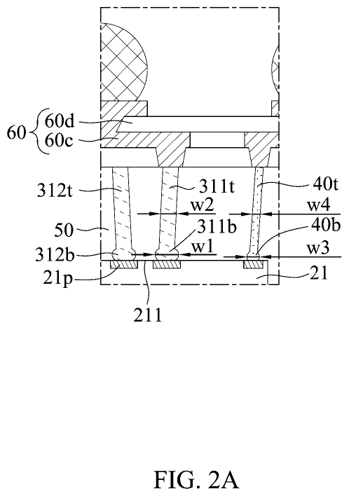

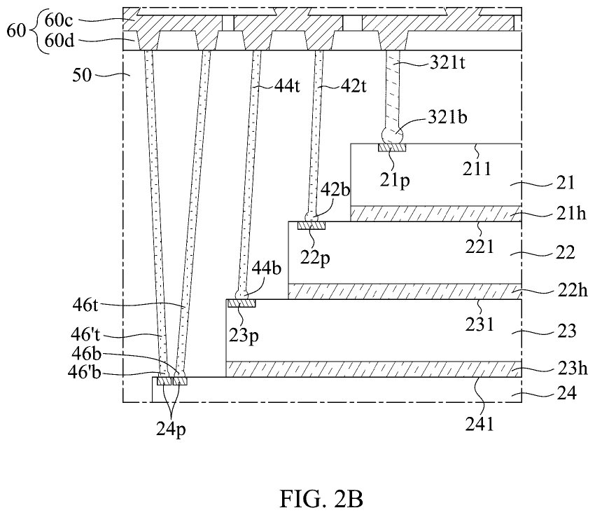

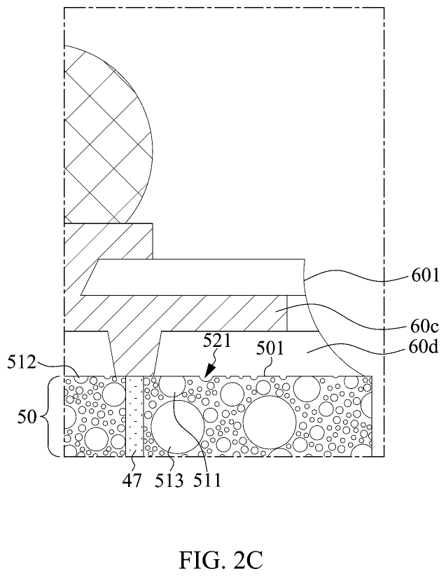

The encapsulant 50 may encapsulate the electronic components 21, 22, 23, and 24, the alignment wires 311, 312, and 321, and the conductive wires 40, 41, 42, 43, 44, 45, 46, 46′, 47, and 48. In some embodiments, top surfaces/ends of the alignment wires 311, 312, and 321, and the conductive wires 40, 41, 42, 43, 44, 45, 46, 46′, 47, and 48 can be exposed by the top surface 501 of the encapsulant 50. The encapsulant 50 may expose an end (endpoint) of the alignment wires 311, 312, and 321 for process identification and positioning. As the alignment wires 311, 312, and 321 are formed by the wire bonding, the package structure 1 may be free of a seed layer between pads (see FIGS. 2A and 2B) of the electronic components 21 and the alignment wire 311, 312, or 321. Likewise, as the conductive wires 40 to 48 are formed by the wire bonding, the package structure 1 is free of a seed layer between the conductive wires 40 to 48 and the pads to which they are connected. In addition, the wire bonding technique provides the alignment wires 311, 312, and 321 with a low aspect ratio, for instance, a ratio of 1:20, which allows for the integration of these wires into thicker structures. The encapsulant 50 may have the top surface 501 substantially coplanar with the end of the alignment wire 311, 312, and 321. After a grinding process performed on the encapsulant to form a planar top surface 501, the RDL 60 may be disposed over the top surface 501 (grinded surface) of the encapsulant 50.

In some embodiments, the encapsulant 50 may include an epoxy resin having fillers dispersed therein, a molding compound (e.g., an epoxy molding compound or other molding compound), PI, a phenolic compound or material, a polymer material with silicone dispersed therein, or a combination thereof.

In some embodiments, the electrical contacts 70 may be disposed on the conductive layer 60c of the RDL 60. The electrical contacts 70 may be disposed on a side of the RDL 60 opposite to the encapsulant 50. The electrical contacts 70 may include conductive bumps, solder elements, solder balls, or the like.

The present disclosure provides the package structure 1 that incorporates one or more wire bonding elements, such as alignment wires 311 and 312, which serve as alignment marks. After the grinding process, these alignment marks, arranged in a specific pattern, can be easily recognized by the machine, thereby improving the alignment necessary for forming a redistribution layer. Additionally, the pitch and dimensions of the wire bonding used as alignment marks can differ from those of other wire bonding, facilitating better identification. In the current practice, the conductive elements for vertical connection are usually formed by a plating process, requiring long process time and high costs. The wire bonding technique can shorten the process time and reduce the manufacturing costs. The use of vertical wire bonding as alignment marks not only improves the accuracy of the alignment process but also aids in establishing vertical electrical connections. Moreover, it can provide more efficient manufacturing processes and enhance performance of semiconductor devices.

FIG. 2A is an enlarged view of region “2A” in FIG. 1, in accordance with some embodiments of the present disclosure. Referring to FIG. 2A, the alignment wires 311 and 312 may be non-perpendicular to the active surface 211 of the electronic component 21 (or the top surface 101 of the substrate 10). The alignment wires 311 and 312 may be straight and inclined or tilted. In some embodiments, the alignment wire 312 may be incline or tilt in a direction different from the alignment wire 311. The alignment wires 311 and 312 may be tilted in different directions with the same tilted degree (angle). In some embodiments, the conductive wire 40 may be straight and substantially parallel to the alignment wire 311. The conductive wire 40 may incline or tilt in a direction same as the alignment wire 311. The conductive wire 40 and the alignment wires 311 and 312 may be formed in the same process. In another embodiment, the conductive wire 40 and the alignment wires 311 and 312may all incline in the same direction. The conductive wire 40 and the alignment wires 311 and 312 may have the same length/height. In some embodiments, the conductive wire 40 may include a row of conductive wires that be formed in the same process, and thus they incline or tilt toward the same direction.

The alignment wire 311 may have a body 311b and a tail 311t connected to the body 311b. The body 311b of the alignment wire 311 may be attached to a conductive pad 21p of the active surface 211. In some embodiments, the conductive pad 21p may be covered by the encapsulant 50. The width w1 of the body 311b may be greater than a width w2 of the tail 311t. The body 311b may be rounded, such as globular or spherical. The tail 311t may be a rounded pillar, a cylinder, or the like. In some embodiments, the diameter w1 of the body 311b may be greater than the diameter w2 of the tail 311t. The alignment wire 312 may have a body 312b and a tail 312t connected to the body 311b, and include a structure similar to the alignment wire 311.

Similar to the alignment wire 311, the conductive wire 40 may have a body 40b and a tail 40t connected to the body 40b. The body 40b of the conductive wire 40 may be attached to the conductive pad 21p of the active surface 211. The width w3 of the body 40b may be greater than a width w4 of the tail 40t. In some embodiments, the diameter (i.e., the width w3) of the body 40b may be greater than the diameter (i.e., the width w4) of the tail 40t. In some embodiments, the width w3 of the body 40b may be different from the width w1 of the body 311b. For example, the width w3 may be less than the width w1. In some embodiments, the diameter w4 of the body 40b may be different from the diameter w2 of the tail 40t. For example, the diameter w4 may be less than the diameter w2.

FIG. 2B is an enlarged view of region “2B” in FIG. 1, in accordance with some embodiments of the present disclosure. Referring to FIG. 2B, the alignment wire 321 may be non-perpendicular to the active surface 211 of the electronic component 21 (or the top surface 101 of the substrate 10). The alignment wire 321 may be straight and inclined or tilted toward a direction different from the alignment wire 312. The alignment wire 321 may be inclined or tilted in the same direction as the alignment wire 311.

In some embodiments, the conductive wire 42 may be connected to conductive pads 22p of the electronic component 22. In some embodiments, the conductive wire 42 may be inclined or tilted toward the same direction as the alignment wire 321 and at different angle of inclination (i.e., the tilted degree). For example, a tilted degree of the alignment wire 321 is less than that of the conductive wires 42. The conductive wires 42 may be longer than the alignment wires 321. In other embodiments, the conductive wire 42 may be inclined or tilted in a direction different from the alignment wire 321. A first angle formed by the alignment wires 321 and the top surface 501 is closer to 90° than a second angle formed by the conductive wire 42 and the top surface 501. That is, the first angle is more perpendicular or orthogonal to the top surface 501 than the second angle is.

In some embodiments, the conductive wire 44 may be connected to conductive pads 23p of the electronic component 23. In some embodiments, the conductive wire 44 may be inclined or tilted toward the same direction as the conductive wire 42 and at different angle of inclination (i.e., the tilted degree). For example, a tilted degree of the conductive wire 42 is less than that of the conductive wires 44. The conductive wires 44 may be longer than the conductive wires 42. In other embodiments, the conductive wire 44 may be inclined or tilted in a direction different from the conductive wire 42. The second angle formed by the conductive wires 42 and the top surface 501 is closer to 90° than a third angle formed by the conductive wire 44 and the top surface 501. That is, the second angle is more perpendicular or orthogonal to the top surface 501 than the third angle is.

In some embodiments, the conductive wires 46 and 46′ are connected to conductive pads 24p of the electronic component 24. The conductive wire 46 may be inclined or tilted toward the same direction as the alignment wire 321 and the conductive wires 42 and 44 and at different angle of inclination (i.e., the tilted degree). The conductive wires 46 may be longer than the alignment wires 321 and the conductive wires 42 and 44. That is, the alignment wire 321, the conductive wires 42, 44, and 46 may be inclined or tilted in the same direction and at different angle of inclination (i.e., the tilted degree). In some embodiments, the longer conductive wires may have a greater tilted degree. The third angle formed by the conductive wires 44 and the top surface 501 is closer to 90° than a fourth angle formed by the conductive wire 46 and the top surface 501. That is, the third angle is more perpendicular or orthogonal to the top surface 501 than the fourth angle is.

The conductive wires 46′ may be inclined or tilted toward a direction different from the alignment wire 321 and at different angle of inclination (i.e., the tilted degree). The length of the conductive wires 46′ may be the same as the conductive wire 46. The conductive wires 46 and 46′ may be inclined or tilted toward the different directions and at the same angle of inclination (i.e., the tilted degree).

Similar to alignment wire 311, alignment wire 321 may have a body 321b and a tail 321t connected thereto. The body 321b of the alignment wire 321 may be attached to the conductive pad 21p of the electronic component 21.

Similar to the conductive wire 40, the conductive wire 42 may have a body 42b and a tail 42t connected to the body 42b. The body 42b of the conductive wire 42 may be attached to the conductive pad 22p of the electronic component 22. Similar to the conductive wire 40, the conductive wire 44 may have a body 44b and a tail 44t connected to the body 44b. The body 44b of the conductive wire 44 may be attached to the conductive pad 23p of the electronic component 23. Similar to the conductive wire 40, the conductive wire 46 may have a body 46b and a tail 46t connected to the body 46b. The body 46b of the conductive wire 46 may be attached to the conductive pad 24p of the electronic component 24. Same as the conductive wire 46, the conductive wire 46′ may have a body 46′b and a tail 46′t connected to the body 46′b. The body 46′b of the conductive wire 46′ may be attached to the conductive pad 24p of the electronic component 24.

In some embodiments, the width of the bodies 42b, 44b, 46b, and 46′b may be different from the width of the body 321b. For example, the diameter of the bodies 44b, 46b, and 46′b may be less than the diameter of the body 321b. In some embodiments, the diameter of the tail 42t, 44t, 46t, and 46′t may be different from the diameter of the tail 321t. For example, the diameter of the tail 42t, 44t, 46t, and 46′t may be less than the diameter of the tail 321t.

FIG. 2C is an enlarged view of region “2C” in FIG. 1, in accordance with some embodiments of the present disclosure. Referring to FIG. 2C, the encapsulant 50 may include a plurality of fillers and the RDL 60 may have a curved lateral surface 601. In some embodiments, the lateral surface 601 of the RDL 60 may be recessed from a lateral surface of the encapsulant 50. That is, the width of the RDL 60 may be less than that of the encapsulant 50.

Each of the fillers of the encapsulant 50 may have different filler sizes. In some embodiments, the fillers may contact the conductive wire 47 and covered by the dielectric layers 60d. The encapsulant 50 may include fillers 511, 512, and 513. In some embodiments, the filler 511 is incomplete since a portion is removed by grinding process. The removed portion of the filler 511 may be less than 50% of the original amount. The top surface of the filler 511 is formed by the grinding process to be substantially planar. Similar to the filler 511, the filler 512 is also incomplete. The removed portion of the filler 512 may be greater than or equal to 50% of the original amount. The top surface of the filler 512 is formed by the grinding process to be substantially planar. In some embodiments, the filler 513 may have a relatively larger diameter. For example, the diameter of the filler 513 may be equal to or greater than the thickness of one dielectric layer 60d.

In some embodiments, the encapsulant 50 may have one or more recesses 521 recessed from the top surface 501, as some of the fillers may be entirely removed during the grinding process. A portion of the dielectric layer 60d may fill in the recesses 521. Accordingly, the portion of the dielectric layer 60d may laterally (or horizontally) overlap the conductive wire 47 (or the alignment marks 31 and 32).

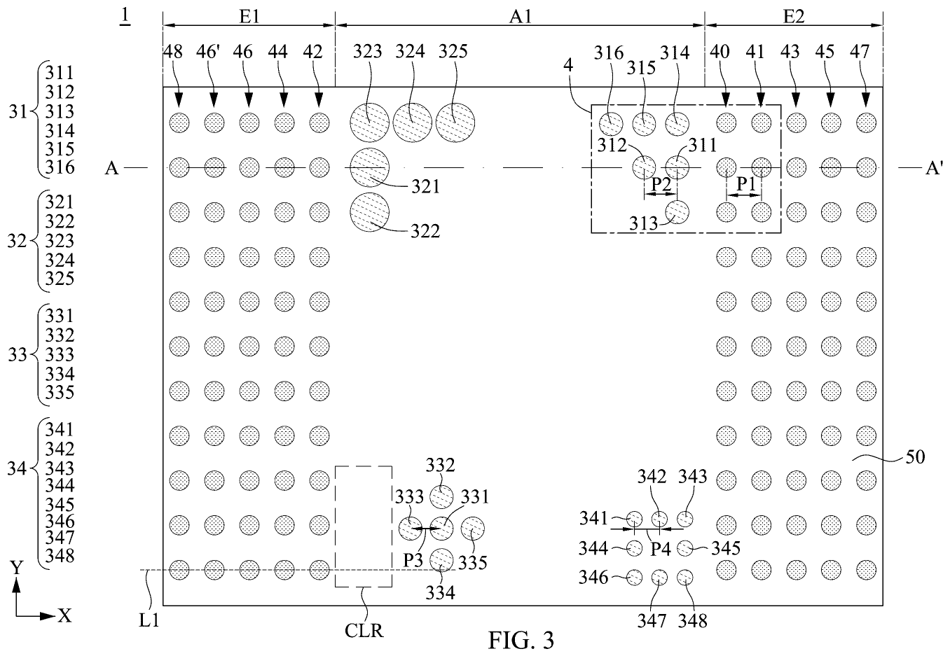

FIG. 3 is a top view of a package structure 1, in accordance with some embodiments of the present disclosure. FIG. 1 is the cross-section of the package structure 1 along line A-A′ of FIG. 3. FIG. 3 omits the RDL 60 and the electrical contacts 70 for clarity. Referring to FIG. 3, the package structure 1 may include one or more alignment marks 31, 32, 33, and 34, and conductive wires 40, 41, 42, 43, 44, 45, 46, 46′, 47, and 48. That is, FIG. 3 is a perspective view that the alignment marks 31, 32, 33, and 34, and conductive wires 40, 41, 42, 43, 44, 45, 46, 46′, 47, and 48 are exposed by the top surface 501 of the encapsulant 50.

In some embodiments, the top surface 501 can include an alignment region A1 and two electrical connection regions E1 and E2. The alignment region A1 is surrounded by and adjacent to the electrical connection regions E1 and E2. The alignment region A1 is between the electrical connection regions E1 and E2. The electrical connection region E1 or E2 is closer to a corner of the encapsulant 50 than the alignment region A1 is. The alignment marks 31, 32, 33, and 34 may be disposed in the alignment region A1. The top surfaces of the alignment marks 31, 32, 33, and 34 may be presented in the alignment region A1. In some embodiments, the alignment marks 32 and 33 may be close to a corner of the electrical region E1, and the alignment marks 31 and 34 may be close to a corner of the electrical region E2. The conductive wires 42, 44, 46, 46′, and 48 are disposed in the electrical connection region E1. The top surfaces of the conductive wires 42, 44, 46, 46′, and 48 may be presented in the electrical connection region E1. The conductive wires 40, 41, 43, 45, and 47 are disposed in the electrical connection region E2. The top surfaces of the conductive wires 40, 41, 43, 45, and 47 may be presented in the electrical connection region E2.

The top surfaces/ends of the conductive wires 40, 41, 42, 43, 44, 45, 46, 46′, 47, and 48 may be define or constitute a conductive pattern, which may geometrically distinct from the alignment patterns (i.e., the alignment marks 31, 32, 33, and 34). For example, the conductive wires 40, 41, 42, 43, 44, 45, 46, 46′, 47, and 48 may be arranged in a row or array. In some embodiments, the conductive wires 40 and 41, 43, 45, and 47 may be five parallel rows. The conductive wires 42, 44, 46, 46′, and 48 may be five parallel rows. The conductive wires 40 and 41, 43, 45, and 47 may be disposed at a side of the package structure 1, and the conductive wires 42, 44, 46, 46′, and 48 may be disposed at another side of the package structure 1. In some embodiments, the conductive wires 40 and 42 may be two parallel rows on opposite sides of the alignment marks 31, 32, 33, and 34 (i.e., the electronic component 21).

In some embodiments, the conductive wires 40, 41, 42, 43, 44, 45, 46, 46′, 47, and 48 may have a pitch P1 between any two adjacent wires, which may be spaced apart by the pitch P1 along the Y-axis. The adjacent two of the conductive wires 40 may be spaced apart by the pitch P1 along the Y-axis. The adjacent two of the conductive wires 41 may be spaced apart by the pitch P1 along the Y-axis. The adjacent two of the conductive wires 43 may be spaced apart by the pitch P1 along the Y-axis. The adjacent two of the conductive wires 45 may be spaced apart by the pitch P1 along the Y-axis. The adjacent two of the conductive wires 47 may be spaced apart by the pitch P1 along the Y-axis. The adjacent two rows of the conductive wires (such as the conductive wires 40 and 41) may be spaced apart by the pitch P1 along the X-axis. The adjacent two of the conductive wires 42 may be spaced apart by the pitch P1 along the Y-axis. The adjacent two of the conductive wires 44 may be spaced apart by the pitch P1 along the Y-axis. The adjacent two of the conductive wires 46 may be spaced apart by the pitch P1 along the Y-axis. The adjacent two of the conductive wires 46′ may be spaced apart by the pitch P1 along the Y-axis. The adjacent two of the conductive wires 48 may be spaced apart by the pitch P1 along the Y-axis. The adjacent two of the conductive wires 42 and 44 may be spaced apart by the pitch P1 along the X-axis.

In some embodiments, the alignment marks 31, 32, 33, and 34 may be disposed between the conductive wires 41 and 42. The alignment marks 31, 32, 33, and 34 may be disposed over the active surface of the electronic component 21 (not shown). The alignment marks 31, 32, 33, and 34 may be geometrically distinct from the conductive wires 40, 41, 42, 43, 44, 45, 46, 46′, 47, and 48. The alignment marks 31, 32, 33, and 34 may be spaced apart from each other by a space. The alignment marks 31, 32, 33, and 34 may be disposed at the corner of the electronic component 21. Each of the alignment marks 31, 32, 33, and 34 may include a predetermined pattern defined by several alignment wires. In particular, the top surfaces/ends of the alignment wires of the alignment marks 31, 32, 33, and 34 may define or constitute an alignment pattern. The predetermined pattern may include a cross, L-shape, stepped, triangle, rectangle, or other suitable shapes. In some embodiments, the alignment marks 31, 32, 33, and 34 may include at least three alignment wires.

The alignment mark 31 may include six (6) alignment wires 311, 312, 313, 314, 315, and 316 collaboratively defining a pattern (an alignment pattern), such as stepped. In some embodiments, the alignment wires 311, 312, and 313 may define an alignment pattern, such as an L-shape. The alignment wire 312 may be spaced apart from the alignment wire 311 along the X-axis, and the alignment wire 313 may be spaced apart from the alignment wire 311 along the Y-axis. In some embodiments, the alignment wires 311, 313, and 314 may be arranged in a straight line as a first row. The alignment wires 312 and 315 may be arranged in a straight line as a second row adjacent to the first row. The alignment wire 316 may be arranged in a third row adjacent to the second row. The imaginary line of the alignment wires 311, 313, and 314 may intersect the imaginary line of the alignment wires 314, 315, and 316.

The two adjacent wires along either the X-axis or the Y-axis of alignment wires 311, 312, 313, 314, 315, and 316 may have a pitch P2. For example, the alignment wires 311 and 312 may be spaced apart by the pitch P2. The alignment wires 311 and 313 may be spaced apart by the pitch P2. In some embodiments, the pitch P1 between two adjacent wires of the conductive wires 40 to 48 may be identical to the pitch P2 between two adjacent wires of the alignment wires 311 to 316.

In some embodiments, the diameter of the alignment wires 311 to 316 of the alignment mark 31 may be different from that of the conductive wires 40 to 48. The diameter of the alignment wires 311 to 316 of the alignment mark 31 may be greater than that of the conductive wires 40 to 48. For example, the diameter of the alignment wires 311 to 316 may be 1.1 times, 1.2 times, 1.5 times, 1.8 times, or twice, the diameter of the conductive wires 40 to 48 or more. In another embodiment, the diameter of the alignment wires 311 to 316 of the alignment mark 31 may be substantially identical to that of the conductive wires 40 to 48.

Some of the alignment wires 311, 312, 313, 314, 315, and 316 may electrically connect to the conductive layer 60c of the RDL 60, and others electrically connected to the dielectric layer 60d. That is, some of the alignment wires may serve as the alignment marks and the vertical conductive wire for electrical connection simultaneously, and some may only serve the alignment marks. In some cases, all alignment wires of the alignment mark 31 may be connected to the dielectric layer 60d (for alignment only). Accordingly, the alignment mark 31 may have flexibility to provide electrical connection.

The alignment mark 32 may include five (5) alignment wires 321, 322, 323, 324, and 325 collaboratively defining a pattern (an alignment pattern), such as an L-shape. The alignment wires 322 and 323 may be spaced apart from the alignment wire 321 along the Y-axis. In some embodiments, the alignment wires 321, 322, and 323 may be arranged in a straight line as a first row along the Y-axis. The alignment wires 323, 324, and 325 may be arranged in a straight line as a second row along the X-axis. The second row may be perpendicular to and intersect the first row to form an L-shape.

In some embodiments, the two adjacent wires along either the X-axis or the Y-axis of alignment wires 321, 322, 323, 324, and 325 may have a pitch P2 substantially identical to the pitch P1. For example, the alignment wires 321 and 322 may be spaced apart by the pitch P2. In another embodiment, the pitch P2 may be different from (for example, less than) the pitch P1. In some embodiments, the diameter of the alignment wires 321 to 325 of the alignment mark 32 may be different from that of the conductive wires 40 to 48. The diameter of the alignment wires 321 to 325 of the alignment mark 32 may be greater than that of the conductive wires 40 to 48. For example, the diameter of the alignment wires 321 to 325 may be 1.2 times, 1.5 times, 1.8 times, or twice the diameter of the conductive wires 40 to 48 or more. In some embodiments, the diameter of the alignment wires 321 to 325 can be greater than the diameter of the alignment wires 311 to 316.

The alignment mark 33 may include five (5) alignment wires 331, 332, 333, 334, and 335 collaboratively defining a pattern (an alignment pattern), such as a cross. The alignment wires 331 may be surrounded by the alignment wires 332, 333, 334, and 335. The alignment wires 332 and 334 may be spaced apart from the alignment wire 331 along the Y-axis. The alignment wires 333 and 335 may be spaced apart from the alignment wire 331 along X-axis. In some embodiments, the alignment wires 331, 332, and 334 may be arranged in a straight line as a first row along the Y-axis. In some embodiments, the alignment wires 331, 333, and 335 may be arranged in a straight line as a second row along the X-axis, where the second row may be perpendicular to and intersect the first row to form a cross.

In some embodiments, the two adjacent wires along either the X-axis or the Y-axis of alignment wires 331, 332, 333, 334, and 335 may have a pitch P3 different from the pitch P1. For example, the pitch P3 may be less than the pitch P1. The pitch P3 may be less than the pitch P2. In some embodiments, the alignment wires 331 and 333 may be spaced apart by the pitch P3. In some embodiments, the conductive wire 40 to 48 may misalign the alignment wires 331 to 335 of the alignment mark 33. For example, referring to FIG. 3, an imaginary line L1 extending along the X-axis connects the centers of the conductive wire 42, 44, 46, 46′, and 48, while the line L1 does not pass through the center of the alignment wire 334.

In some embodiments, the diameter of the alignment wires 331 to 335 of the alignment mark 33 may be different from that of the conductive wires 40 to 48. The diameter of the alignment wires 331 to 335 of the alignment mark 33 may be greater than that of the conductive wires 40 to 485. For example, the diameter of the alignment wires 331 to 335 may be 1.2 times, 1.5 times, 1.8 times, or twice the diameter of the conductive wires 40 to 48, or more.

In some embodiments, the alignment mark 33 may be spaced apart from the conductive wires 42 by a distance or a clearance zone CLR. That is, the clearance zone CLR is between the alignment wires 331 to 335 and the conductive wires 42. In some embodiments, a width of the clearance zone CLR (along the X-axis) may be greater than the diameter of the top surfaces of the alignment wires of the alignment mark 33. With the clearance zone CLR between the conductive wires (for example, the conductive wires 42) and the alignment mark (for example, the alignment mark 33), identification of the alignment mark can be facilitated. In some embodiments, the clearance zone CLR can be arranged between any alignment mark and the conductive wires.

The alignment mark 34 may include eight (8) alignment wires 341, 342, 343, 344, 345, 346, 347, and 348 collaboratively defining a pattern (an alignment pattern), such as a rectangle. In some embodiments, the alignment wires 341, 342, and 343 may be arranged in a straight line as a first row along the X-axis. The alignment wires 343, 345, and 348 may be arranged in a straight line as a second row along the Y-axis, where the second row may be perpendicular to and intersect the first row. The alignment wires 346, 347, and 348 may be arranged in a straight line as a third row along the X-axis, where the third row may be perpendicular to and intersect the second row. The alignment wires 341, 344, and 346 may be arranged in a straight line as a fourth row along the Y-axis, where the fourth row may be perpendicular to and intersect the first row and the third row.

In some embodiments, the two adjacent wires along either the X-axis or the Y-axis of alignment wires 341, 342, 343, 344, 345, 346, 347, and 348 may have a pitch P4 different from the pitch P1. For example, the pitch P4 may be less than the pitch P1. The pitch P4 may be less than the pitch P3. In some embodiments, the alignment wires 341 and 342 may be spaced apart by the pitch P4. In some embodiments, the conductive wire 40 to 48 may misalign the alignment wires 341 to 348 of the alignment mark 34.

In some embodiments, the diameter of the alignment wires 341 to 348 of the alignment mark 34 may be different from that of the conductive wires 40 to 48. The diameter of the alignment wires 341 to 348 of the alignment mark 34 may be less than that of the conductive wires 40 to 48. For example, the diameter of the alignment wires 341 to 345 may be 0.9, 0.7, or 0.5 times the diameter of the conductive wires 40 to 48, or less.

Similar to the alignment mark 31, the alignment marks 32, 33, and 34 may have wires providing alignment and electrical connection between the electronic component 21 and the RDL 60 simultaneously. The exposed ends (top surfaces) of the alignment wires of the alignment marks 31, 32, 33, and 34 can be configured to indicate the position (or boundary) of the electronic component 21 that is encapsulated by the encapsulant 50 during the manufacturing of the RDL 60 for process identification and positioning. The alignment marks can be arranged in a specific pattern that can be easily identified and provide electrical connection as well. Furthermore, the alignment wires of the alignment marks and the conductive wires may have different pitches and/or different diameters, such that the alignment marks can be easily distinguished from the conductive wires to identify the boundary of the molded electronic component. Moreover, the alignment marks can include the clearance zone CLR between the alignment wires and the conductive wires for better identification.

FIG. 3 provides several embodiments of alignment patterns. In some embodiments, the alignment marks of the package structure 1 can be the same pattern. Alternatively, the alignment marks of the package structure 1 can be different for specific purpose, such as the positioning of a critical element.

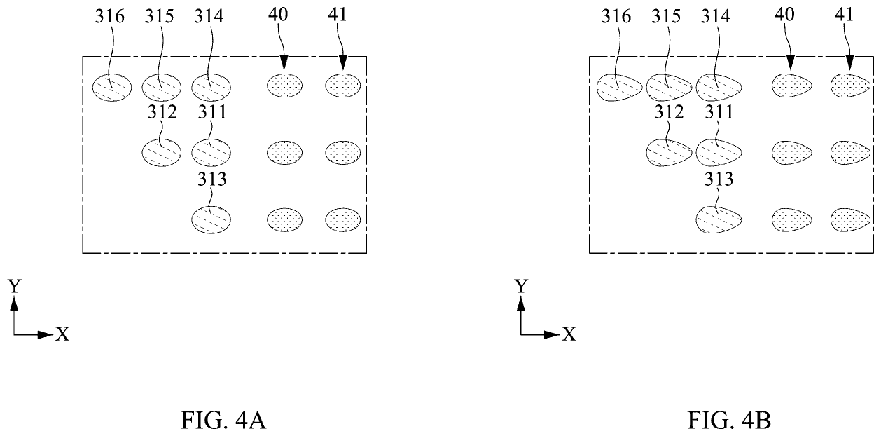

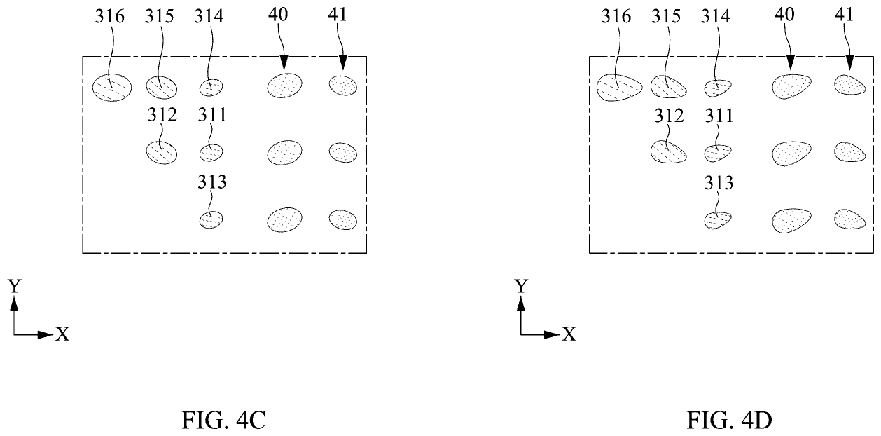

FIG. 4A is an enlarged view of region “4” in FIG. 3, in accordance with some embodiments of the present disclosure. Referring to FIG. 4A, the conductive wires 40 and 41 and the alignment wires 311 to 316 may be elliptical. In some embodiments, the alignment wire 311 may be substantially the same shape as the conductive wire 40. The alignment wires 311 to 316 may extend along the same orientation. The conductive wires 40 and 41 may be parallel. In some embodiments, the major axis of the alignment wires 311 to 316 and the conductive wires 40 and 41 may be parallel to the X-axis. Each of the alignment wires 311 to 316 may be aligned with one of the conductive wires 40 and 41 along the X-axis.

In some embodiments, the size of the alignment wires 311 to 316 of the alignment mark 31 may be different from that of the conductive wires 40 and 41. The size of the alignment wires 311 to 316 of the alignment mark 31 may be greater than that of the conductive wires 40 to 48. For example, the width of the alignment wires 311 to 316 may be 1.1 times, 1.2 times, 1.5 times, 1.8 times, or twice the width of the conductive wires 40 to 48, or more. In another embodiment, the size of the alignment wires 311 to 316 of the alignment mark 31 may be substantially identical to those of the conductive wires 40 to 48.

FIG. 4B is an enlarged view of region “4” in FIG. 3, in accordance with some embodiments of the present disclosure. FIG. 4B is similar to FIG. 4A, differing therefrom in the shape of the conductive wires 40 and 41 and the alignment wires 311 to 316. Referring to FIG. 4B, the conductive wires 40 and 41 and the alignment wires 311 to 316 may be irregularly rounded, for example in a teardrop shape.

FIG. 4C is an enlarged view of region “4” in FIG. 3, in accordance with some embodiments of the present disclosure. FIG. 4C is similar to FIG. 4A, differing therefrom in the orientations and dimensions of the conductive wires 40 and 41 and the alignment wires 311 to 316.

Referring to FIG. 4C, the alignment wires located internally (i.e., proximate to the center of the electronic component 21) may have a larger area on their top surface. That is, the area of the alignment wire 316 (in the first row) may be larger than that of the alignment wires 311 to 315. The area of the alignment wire 312 and 315 (in the second row) may be larger than that of the alignment wires 311, 313, and 314 (in the third row).

Furthermore, the orientation of the alignment wires 311 to 316 may vary. In some embodiments, each vertical row of alignment wires may be oriented in different directions, while alignment wires in the same row may have the same orientation. That is, the alignment wires 312 and 315 may have the same orientation, and the alignment wires 311, 313, and 314 may have the same orientation. The alignment wire 316 in the first row and the alignment wires 312 and 315 in the second row may be oriented in different directions. In other words, the major axis of the alignment wires 312 and 315 in the second row extend in a direction different from a major axis of the alignment wire 316 in the first row. The alignment wires 311, 313, and 314 in the third row and the alignment wires 312 and 315 in the second row may be oriented in different directions. In other words, the major axis of the alignment wires 312 and 315 in the second row extend in a direction different from the major axis of the alignment wires 311, 313, and 314 in the third row.

Similar to the alignment wires, the conductive wires located internally (i.e., proximate to the center of the electronic component 21) may have a larger area on their top surface. That is, the area of the conductive wires 40 may be larger than that of the conductive wires 41. In addition, the orientation of the conductive wires 40 and 41 may vary. In some embodiments, each vertical row of conductive wires 40 and 41 may be oriented in different directions, while conductive wires in the same row may have the same orientation. The conductive wires 40 may have the same orientation. The conductive wires 41 may have the same orientation. The conductive wires 40 may be oriented differently from the conductive wires 41.

FIG. 4D is an enlarged view of region “4” in FIG. 3, in accordance with some embodiments of the present disclosure. FIG. 4D is similar to FIG. 4C, differing therefrom in the shape of the conductive wires 40 and 41 and the alignment wires 311 to 316. Referring to FIG. 4D, the conductive wires 40 and 41 and the alignment wires 311 to 316 may be irregularly rounded, for example in a teardrop shape.

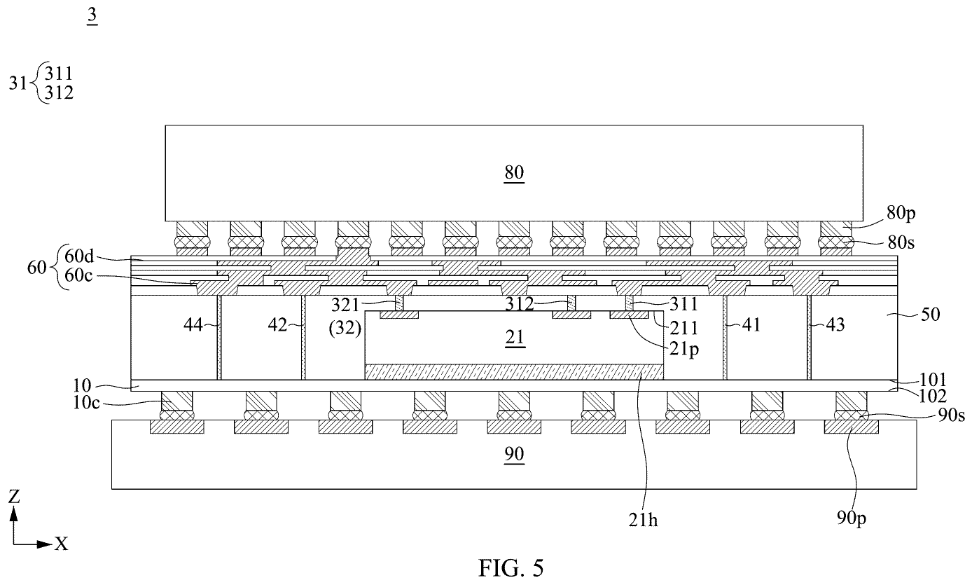

FIG. 5 is a cross-section of a package structure 3, in accordance with some embodiments of the present disclosure. The package structure 3 is similar to the package structure 1 in FIG. 1, differing therefrom in the arrangements of electronic components and conductive wires with additional elements included. The package structure 3 may include a substrate 10, electronic components 21 and 80, alignment marks 31 and 32, conductive wires 41, 42, 43, and 44, an encapsulant 50, a redistribution layer (RDL) 60, and a carrier 90. Compared with the package structure 1, the package structure 3 include merely one electronic component 21 encapsulated by the encapsulant 50, an additional electronic component 80 connected to the electronic component through the RDL 60, and a carrier 90 supporting the substrate 10.

Referring to FIG. 5, the carrier 90 may be disposed under the bottom surface 102 of the substrate 10. The carrier 90 may include, for example, a printed circuit board, such as a paper-based copper foil laminate, a composite copper foil laminate, or a polymer-impregnated glass-fiber-based copper foil laminate. The carrier 90 may include an interconnection structure, such as a plurality of conductive traces and/or a plurality of conductive vias. In some embodiments, the carrier 90 includes a ceramic material, a metal plate, an organic substrate, or a leadframe. In some embodiments, the carrier 90 may include a two-layer substrate which includes a core layer and a conductive material and/or structure disposed on an upper surface and a bottom surface of the carrier 90. The conductive material and/or structure may include a plurality of conductive traces. In some embodiments, the carrier 90 includes one or more conductive pads 90p exposed from the top surface.

The conductive pads 90p of the carrier 90 may be connected to conductive pads 10c of the substrate 10 that protrude from the bottom surface 102 through solder elements 90s. The solder elements 90s may include conductive bumps, solder balls, or the like. In some embodiments, the size of the carrier 90 may be different from that of the substrate 10. Carrier 90 may be wider and thicker than substrate 10.

In some embodiments, the electronic component 21 attaches to the top surface 101 of the substrate 10 through the adhesive layer 21h. In some embodiments, the alignment marks 31 and 32 may be disposed on and connected to the active surface 211 of the electronic component 21. The alignment marks 31 and 32 may be disposed adjacent to opposite sides or edges of the electronic component 21. In some embodiments, the alignment marks 31 and 32 may be disposed at corners of the electronic component 21. The alignment mark 31 may include alignment wires 311 and 312 extending between the RDL 60 and the active surface 211 and connected to the conductive pads 21p. The alignment mark 32 may include an alignment wire 321 extending between the RDL 60 and the active surface 211 and connected to the conductive pads 21p.

The conductive wires 41, 42, 43, and 44 may be disposed on the substrate 10. The conductive wires 41 and 43 may be located at one side of the substrate 10, and the conductive wires 42 and 44 may be located at the opposite side of the substrate 10 in relation to the electronic component 21. The conductive wires 41, 42, 43, and 44 may extend between the RDL 60 and the top surface 101 of the substrate 10. The conductive wires 41, 42, 43, and 44 may electrically connect to pads (not shown) of the substrate 10.

In some embodiments, the conductive wire 41 is spaced apart from the alignment mark 31 (i.e., the alignment wires 311 and 312) by a distance. The conductive wire 42 is spaced apart from the alignment mark 32 (i.e., the alignment wire 321) by a distance. In some embodiments, the conductive wires 41, 42, 43, and 44 may be of different lengths (for example, longer) than the alignment wires 311, 312, and 321. The conductive wires 41, 42, 43, and 44 may be of substantially the same length. The conductive wires 41, 42, 43, and 44 may be parallel. The conductive wires 41 to 44 in FIG. 5 are similar to the conductive wires 40 to 48 in FIG. 1, differing only in location and length.

In some embodiments, the electronic component 80 may be disposed on the RDL 60 and electrically connected to the electronic component 21. The electronic component 80 may include one or more conductive pads 80p facing the RDL 60. The conductive pads 80p of the electronic component 80 may be connected to the conductive layer 60c of the RDL 60 through solder elements 80s. The solder elements 80s may include conductive bumps, solder balls, or the like. In some embodiments, the electronic component 80 may electrically connect to the carrier 90 through the RDL 60, the conductive wires 41 to 44, and the substrate 10.

In some embodiments, the size of the electronic component 80 may be different from that of the RDL 60. The width of the electronic component 80 may be less than that of the RDL 60. Electronic component 80 may be of different size than electronic component 21, such as wider and/or thicker.

The electronic component 80 may be a chip or die including a semiconductor substrate, one or more integrated circuit devices and one or more overlying interconnection structures therein. The integrated circuit devices may include active devices such as transistors and/or passive devices such resistors, capacitors, inductors, or a combination thereof. In some arrangements, the electronic component 80 includes an active device, e.g., an ASIC, a PMIC, or the like.

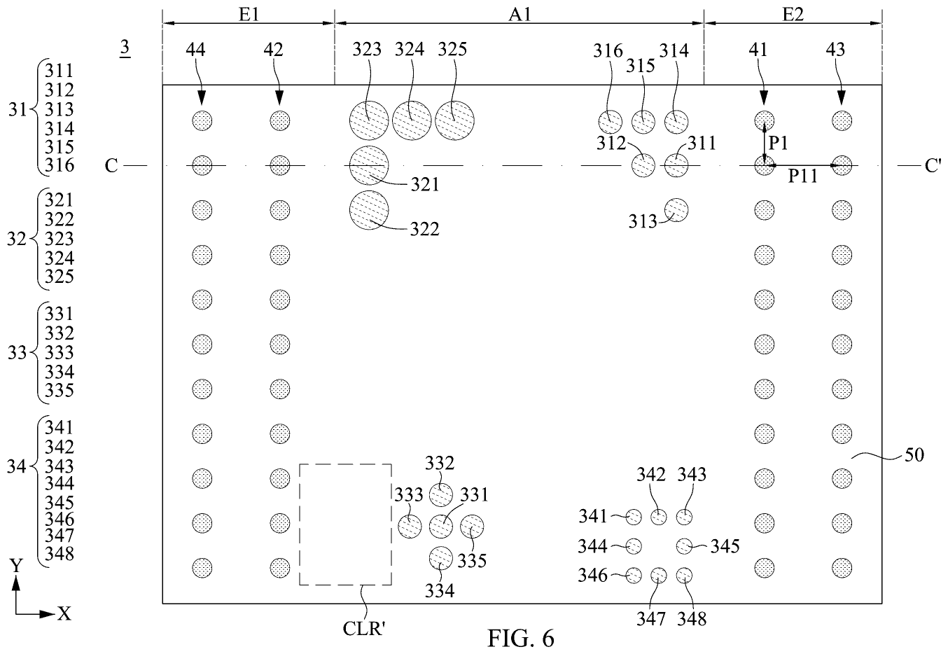

FIG. 6 is a top view of a package structure 3, in accordance with some embodiments of the present disclosure. FIG. 5 is a cross-section of the package structure 3 along line C-C′ of FIG. 6. FIG. 6 omits the electronic component 80 and the RDL 60 for clarity. The package structure 3 is similar to the package structure 1 in FIG. 3, differing therefrom in the distance between adjacent rows of conductive wires. Referring to FIG. 6, adjacent two of the conductive wires 41 may be spaced apart along the Y-axis by the pitch P1. Adjacent two of different rows of the conductive wires 41 and 43 may be spaced apart along the X-axis by a pitch P11. The pitch P11 may be different from (for example, greater than) the pitch P1. In addition, the alignment mark 33 may be spaced apart from the conductive wire 42 by a clearance zone CLR′ that is greater than the clearance zone CLR in FIG. 3.

Package structures 1, 2, and 3 offer distinct configurations utilizing vertical conductive wires for the purpose of electrical connection, as well as employing vertical conductive wires as alignment marks.

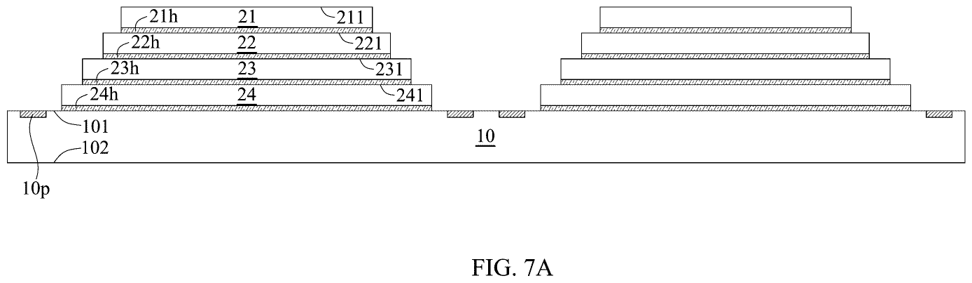

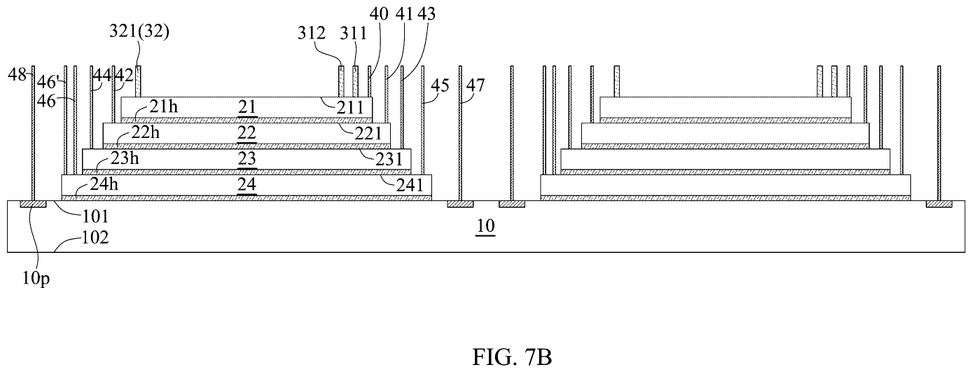

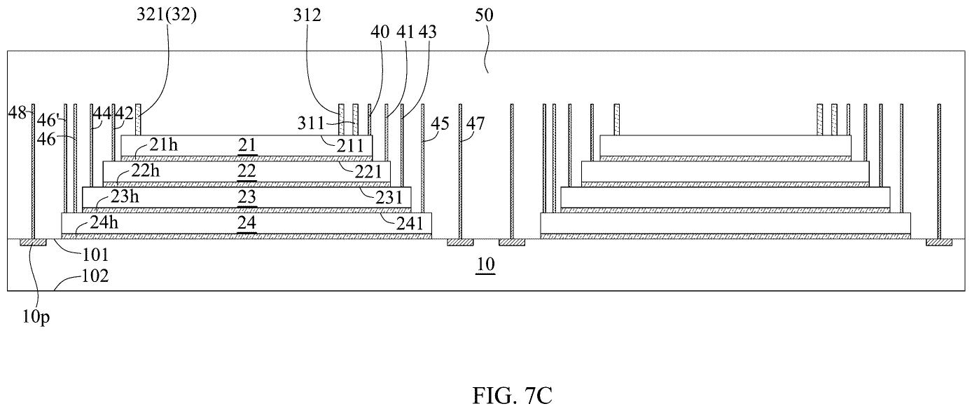

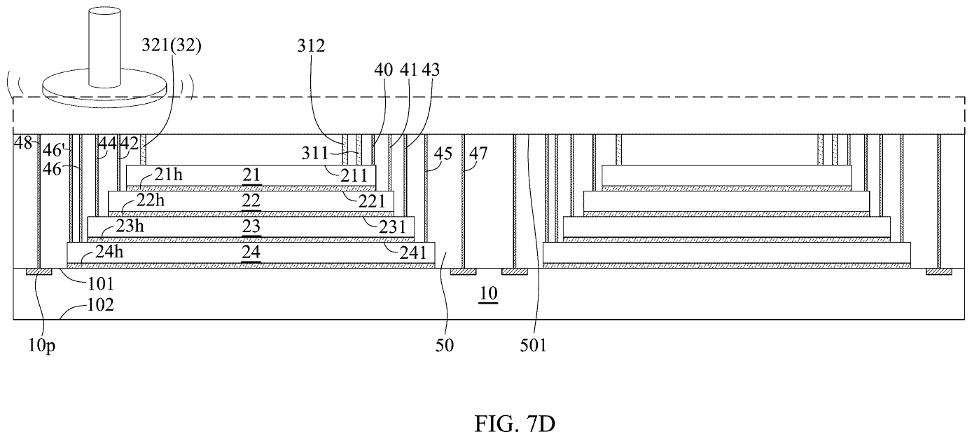

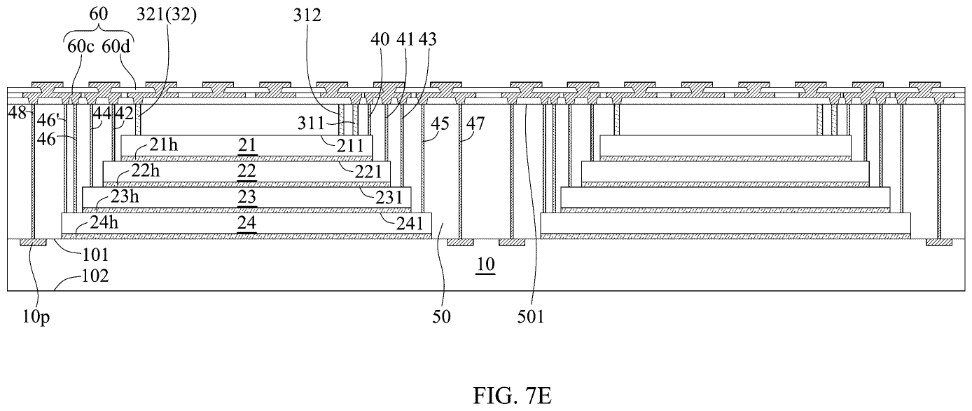

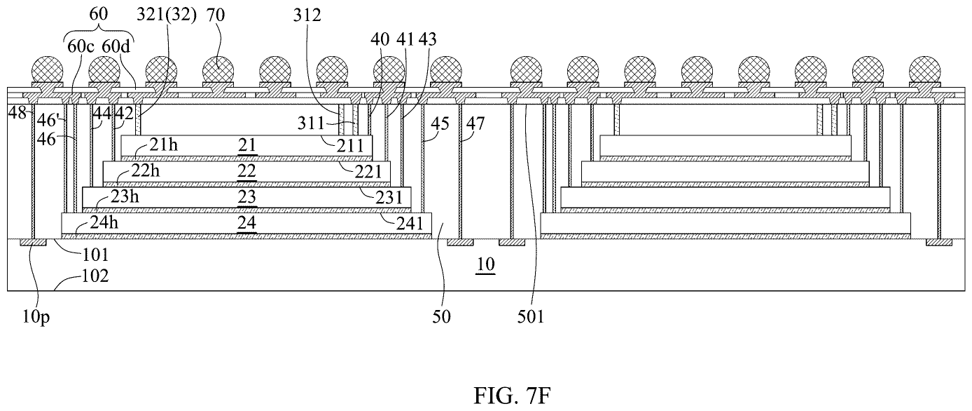

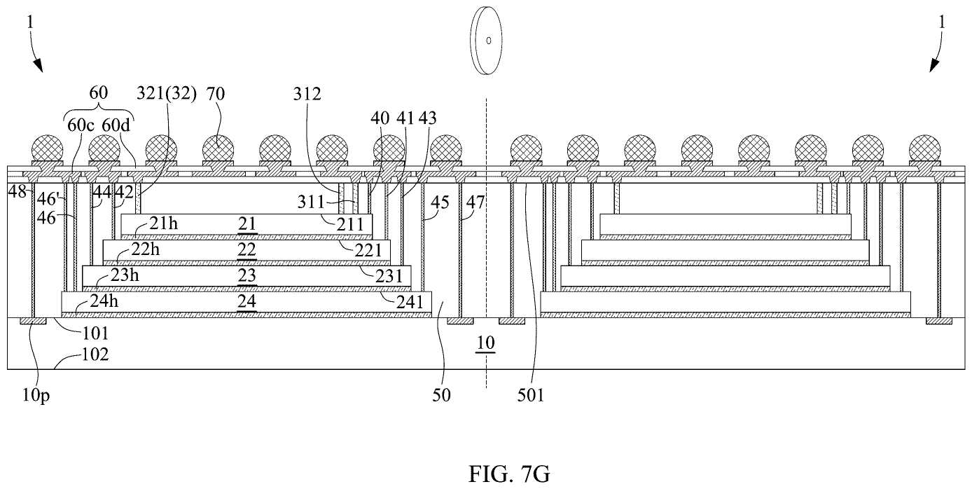

FIG. 7A, FIG. 7B, FIG. 7C, FIG. 7D, FIG. 7E, FIG. 7F, and FIG. 7G illustrate one or more operations of a method for manufacturing a package structure 1, in accordance with some embodiments of the present disclosure.

Referring to FIG. 7A, a substrate 10 is provided with multiple electronic components 21, 22, 23, and 24 attached to the substrate 10. In some embodiments, the substrate 10 has a top surface 101 and a bottom surface 102 opposite thereto. The substrate 10 has pads 10p exposed by the top surface 101. The electronic components 24 can be attached to the top surface 101 of the substrate through the adhesive layer 24h. The electronic components 23 can be attached to the electronic components 24 through the adhesive layer 23h. The electronic components 22 can be attached to the electronic components 23 through the adhesive layer 22h. The electronic components 21 can be attached to the electronic components 22 through the adhesive layer 21h. In some embodiments, the electronic components 21, 22, 23, and 24 can be stacked one another. The electronic components 21, 22, 23, and 24 can have different sizes (widthes).

Referring to FIG. 7B, a wire bonding process is performed on the electronic components 21, 22, 23, and 24 to form alignment wires of the alignment marks 31 and 32 and conductive wires 40, 41, 42, 43, 44, 45, 46, 46′, 47, and 48. The alignment marks 31 and 32 and the conductive wire 40 can be formed on the active surface 211 of the electronic component 21. The conductive wires 41 and 42 can be formed on the active surface 221 of the electronic component 22. The conductive wires 43 and 44 can be formed on the active surface 231 of the electronic component 23. The conductive wires 45, 46, and 46′ can be formed on the active surface 241 of the electronic component 24. The conductive wires 47 and 48 can be formed on the pads 10p exposed on the top surface 101 of the substrate 10.

Referring to FIG. 7C, an encapsulant 50 may be formed on the substrate 10 to encapsulate the electronic components 21, 22, 23, and 24 and the alignment marks 31 and 32 and conductive wires 40, 41, 42, 43, 44, 45, 46, 46′, 47, and 48. The encapsulant 50 may be disposed on and cover the top surface 101 of the substrate 10. The encapsulant 50 may be formed by a molding process.

Referring to FIG. 7D, the encapsulant 50 may be grinded to form a planar top surface 501 and to expose ends of the alignment marks 31 and 32 and conductive wires 40, 41, 42, 43, 44, 45, 46, 46′, 47, and 48.

Referring to FIG. 7E, a redistribution layer (RDL) 60 may be formed on the top surface 501 of the encapsulant 50. The RDL 60 includes dielectric layers 60d and conductive layers 60c at least partially covered by the dielectric layers 60d. The alignment marks 31 and 32 can be easily identified, thereby enhancing the alignment to form the RDL 60.

Referring to FIG. 7F, one or more electrical contacts 70 may be formed on the RDL 60. The electrical contacts 70 may be formed on and connected to the conductive layers 60c of the RDL 60. In some embodiments, the electrical contacts 70 may be solder balls.

Referring to FIG. 7G, the resulting structure in FIG. 7F may be singulated. In some embodiments, a dicing operation may be performed on the wafer or panel. In some embodiments, the dicing operation may be a sawing process, such as laser sawing. Then, a package structure 1 as described and illustrated with reference to FIG. 1 is formed.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A package structure, comprising:
a first semiconductor component;
a second semiconductor component disposed over the first semiconductor component;
a plurality of alignment wires disposed on the second semiconductor component; and
an encapsulant encapsulating the first semiconductor component, the second semiconductor component, and the plurality of alignment wires, wherein the encapsulant has a top surface exposing top surfaces of the plurality of alignment wires,
wherein the top surfaces of the plurality of alignment wires constitute an alignment pattern in a top view.

2. The package structure of claim 1, further comprising:
a plurality of conductive wires disposed on the first semiconductor component and encapsulated by the encapsulant, wherein top surfaces of the plurality of conductive wires are exposed by the top surface of the encapsulant,
wherein the top surface of the encapsulant includes a first region and a second region, wherein the top surfaces of the plurality of alignment wires are presented in the first region, and the top surfaces of the plurality of conductive wires are presented in the second region, and wherein the plurality of conductive wires constitute a conductive pattern in the top view, and wherein the alignment pattern is geometrically distinct from the conductive pattern.

3. The package structure of claim 2, further comprising a clearance zone between the alignment pattern and the conductive pattern in the top view.

4. The package structure of claim 3, wherein a width of the clearance zone is greater than a diameter of one of the top surface of the plurality of alignment wires in the top view.

5. The package structure of claim 2, wherein a shape of one of the top surfaces of the plurality of alignment wires are substantially identical to a shape of one of the top surfaces of the plurality of conductive wires.

6. The package structure of claim 2, wherein a length of the plurality of alignment wires is less than a length of the plurality of conductive wires, wherein a first one of the plurality of alignment wires and the top surface of the encapsulant form a first angle in a cross-sectional view, wherein a first one of the plurality of conductive wires and the top surface of the encapsulant form a second angle in the cross-sectional view, and wherein the first angle is closer to 90° than the second angle is in the cross-sectional view.

7. The package structure of claim 6, wherein the first one of the plurality of alignment wires and the first one of the plurality of conductive wires are tilted in different directions in the cross-sectional view.

8. The package structure of claim 1, further comprising a redistribution layer (RDL) disposed over the top surface of the encapsulant, wherein the RDL includes a conductive layer and a dielectric layer covering the conductive layer, wherein the dielectric layer covers the top surface of the plurality of alignment wires.

9. The package structure of claim 1, wherein the alignment pattern includes a cross in the top view.

10. A package structure, comprising:
a first die having a first active surface;
a second die disposed below the first die and having a second active surface;
an encapsulant encapsulating the first die and the second die and having a first surface, wherein the first surface of the encapsulant includes a first region, a second region, and an alignment region between the first region and the second region;
a plurality of first conductive wires disposed on the second active surface of the second die and encapsulated by the encapsulant, wherein top surfaces of the plurality of first conductive wires are exposed in the first region of the encapsulant;
a plurality of second conductive wires disposed on the second active surface of the second die and encapsulated by the encapsulant, wherein top surfaces of the plurality of second conductive wires are exposed in the second region of the encapsulant; and
a plurality of first alignment wires extending between the first active surface of the first die and the first surface of the encapsulant, wherein top surfaces of the plurality of first alignment wires are exposed in the alignment region and constitute a first alignment mark.

11. The package structure of claim 10, wherein the first alignment mark is close to a corner of the first region.

12. The package structure of claim 10, wherein one of the top surfaces of the plurality of alignment wires is in an elliptical shape in a top view.

13. The package structure of claim 10, wherein a first one and a second one of the top surfaces of the plurality of alignment wires are elliptical, wherein a major axis of the first one extend in a direction different from a major axis of the second one.

14. The package structure of claim 10, further comprising:
a third die disposed below the second die and having an active surface; and
a plurality of third conductive wires disposed on the first active surface of the third die and encapsulated by the encapsulant, wherein top surfaces of the plurality of third conductive wires are exposed in the first region of the encapsulant,
wherein a first one of the plurality of first conductive wires and the top surface of the encapsulant form a first angle in a cross-sectional view, wherein a first one of the plurality of third conductive wires and the top surface of the encapsulant form a second angle in the cross-sectional view, and wherein the first angle is closer to 90° than the second angle is.

15. The package structure of claim 10, further comprising a plurality of second alignment wires extending between the active surface of the first die and the first surface of the encapsulant, wherein top surfaces of the plurality of second alignment wires are exposed in the alignment region and constitute a second alignment mark, wherein the second alignment mark is spaced apart from the first alignment mark, and wherein a pattern of the first alignment mark is different from a pattern of the second alignment mark.

16. The package structure of claim 10, further comprising a redistribution layer (RDL) disposed over the top surface of the encapsulant, wherein the first alignment mark is configured to indicate a position of the first die during the manufacturing of the RDL.

17. The package structure of claim 16, wherein the encapsulant includes a plurality of fillers, wherein the dielectric layer includes a portion filling in a recess of the encapsulant recessed from the first surface, wherein the portion of the dielectric layer overlaps one of the plurality first alignment wires in a direction parallel to the first surface of the encapsulant in the cross-sectional view.

18. A package structure, comprising:
an electronic component having an active surface;
an alignment wire disposed on the active surface;
a conductive wire disposed on the active surface; and
an encapsulant encapsulating the electronic component, the alignment wire, and the conductive wire, wherein top surfaces of the alignment wire and the conductive wire are exposed by the encapsulant,
wherein the conductive wire is closer to an edge of the electronic component than the alignment wire is.

19. The package structure of claim 18, further comprising a redistribution layer (RDL) disposed over the alignment wire, wherein the RDL includes a conductive layer and a dielectric layer partially covering the conductive layer, wherein the dielectric layer contacts the alignment wire.

20. The package structure of claim 18, wherein the electronic component has a pad on the active surface, wherein the package structure is free of a seed layer between the first alignment wire and the pad of the electronic component.
